(19) United States
(12) Patent Application Publication
(10) Pub. No.: US 2024/0038510 A1
(43) Pub. Date: Feb. 1, 2024

(54) METHODS OF PROCESSING SUBSTRATES AND APPARATUSES THEREOF

(71) Applicant: Samsung Electronics Co., Ltd., Suwon-si (KR)

(72) Inventors: Changheon LEE, Hwaseong-si (KR); Sangki NAM, Seongnam-si (KR); Taesun SHIN, Hwaseong-si (KR)

(73) Assignee: Samsung Electronics Co., Ltd., Suwon-si (KR)

(21) Appl. No.: 18/469,208

(22) Filed: Sep. 18, 2023

Related U.S. Application Data
(63) Continuation of application No. 17/319,503, filed on May 13, 2021.

(30) Foreign Application Priority Data
Nov. 5, 2020 (KR) 10-2020-0146941

(51) Int. Cl. H01J 37/32; H01L 21/3065; H01L 21/67

(52) U.S. Cl. CPC H01J 37/32834; H01L 21/3065; H01L 21/67069; H01J 37/3244; H01J 37/32091; H01J 37/32642; H01J 37/32743; H01J 37/32568; H01J 37/3211; H01J 2237/334

(57) ABSTRACT

A substrate processing method includes inserting a substrate from an outside into a processing space, supplying a process gas from a gas supply unit to the processing space, producing plasma based on the process gas, performing an etching process for the substrate using ions included in the plasma, and discharging a processed gas produced in the etching process through a discharge part. The discharge part includes a first slit extending through a flange part, and a second slit connected to the first slit while extending through a side wall part connected to the flange part. A vertical length of the first slit is equal to a vertical length of the second slit. A horizontal length of the first slit is about 5 times to about 7 times the vertical length of the first slit.

### CROSS-REFERENCE TO RELATED APPLICATIONS

This application is a continuation of U.S. application Ser. No. 17/319,503, filed on May 13, 2021 which is based on and claims priority under 35 U.S.C. § 119 to Korean Patent Application No. 10-2020-0146941, filed on Nov. 5, 2020, in the Korean Intellectual Property Office, the disclosure of each of which is incorporated herein by reference in its entirety.

### BACKGROUND

### Field

Some example embodiments of the inventive concepts relate to methods and apparatuses for processing a substrate.

### Description of the Related Art

A semiconductor device is formed through various semiconductor manufacturing processes such as a deposition process, an ion implantation process, a photolithography process and an etching process. Among such semiconductor manufacturing processes, the etching process may be performed using plasma produced from a process gas. In particular, in a vertical NAND (V-NAND) product, there may be defects caused by an etching rate difference between substrate regions generated due to an increase in the number of stacks in a substrate.

### SUMMARY

Some example embodiments of the inventive concepts provide a substrate processing method and apparatus capable of increasing an etching rate in an edge region of a substrate.

A substrate processing method according to some example embodiments of the inventive concepts may include inserting a substrate into a processing space at least partially defined by one or more inner surfaces of a shroud unit from an outside of a volume defined by one or more outer surfaces of the shroud unit, producing plasma based on the process gas, performing an etching process to cause etching of the substrate using ions included in the plasma, and discharging a processed gas produced in the etching process through a discharge part of the shroud unit. The discharge part may include a first slit extending through a flange part, and a second slit connected to the first slit while extending through a side wall part connected to the flange part. A vertical length of the first slit may be equal to a vertical length of the second slit. A horizontal length of the first slit is about 5 times to about 7 times the vertical length of the first slit.

A substrate processing apparatus according to some example embodiments of the inventive concepts may include a process unit, an upper electrode unit at an upper portion of an interior of the process unit, the upper electrode unit configured to receive first radio-frequency (RF) electric power from a first power supply unit, a lower electrode unit at a lower portion of the interior of the process unit, the lower electrode unit configured to receive second RF electric power from a second power supply unit, and a shroud unit between the upper electrode unit and the lower electrode unit within the interior of the process unit. The shroud unit may include a ring-shaped flange part, a side wall part extending vertically from an outer side wall of the flange part, first discharge parts each including a first slit extending through the flange part, and a second slit connected to the first slit while extending through the side wall part, and second discharge parts each including a third slit formed at the side wall part while extending through the flange part.

A substrate processing apparatus according to some example embodiments of the inventive concepts may include a process unit, a supply hole formed to extend through a top wall of the process unit, an upper electrode unit at an upper portion of an interior of the process unit, the upper electrode unit configured to receive first radio-frequency (RF) electric power from a first power supply unit, a lower electrode unit disposed at a lower portion of the interior of the process unit, the lower electrode unit configured to receive second RF electric power from a second power supply unit, a shroud unit between the upper electrode unit and the lower electrode unit within the interior of the process unit, an opening/closing unit outside the shroud unit while surrounding the shroud unit, and a discharge hole extending through a lower wall of the process unit. The shroud unit may include a ring-shaped flange part, a side wall part extending vertically from an outer side wall of the flange part, and a discharge part including a first slit extending through the flange part, and a second slit extending vertically from the first slit while extending through the side wall part. Vertical lengths of the first slit and the second slit may be equal.

### BRIEF DESCRIPTION OF THE DRAWINGS

FIG. 1 is a vertical sectional view of a substrate processing apparatus according to some example embodiments of the inventive concepts.

FIG. 2A is a perspective view of a shroud unit according to some example embodiments of the inventive concepts.

FIG. 2B is a cross-sectional view taken along line I-I′ in FIG. 2A.

FIG. 2C is a side view of a shroud unit according to some example embodiments of the inventive concepts.

FIG. 2D is a bottom view of a shroud according to some example embodiments of the inventive concepts.

FIG. 3A is a bottom view of a shroud unit and an opening/closing member according to some example embodiments of the inventive concepts.

FIG. 3B is a bottom view of a shroud unit and an opening/closing member according to some example embodiments of the inventive concepts.

FIG. 4A is a perspective view of a shroud unit according to some example embodiments of the inventive concepts.

FIG. 4B is a side view of the shroud unit according to some example embodiments of the inventive concepts.

FIG. 5A is a perspective view of a shroud unit according to some example embodiments of the inventive concepts.

FIG. 5B is a side view of the shroud unit according to some example embodiments of the inventive concepts.

FIG. 6A is a perspective view of a shroud unit according to some example embodiments of the inventive concepts.

FIG. 6B is a side view of the shroud unit according to some example embodiments of the inventive concepts.

FIGS. 7A, 7B, and 7C are schematic views of a substrate processing method according to some example embodiments of the inventive concepts.

### DETAILED DESCRIPTION

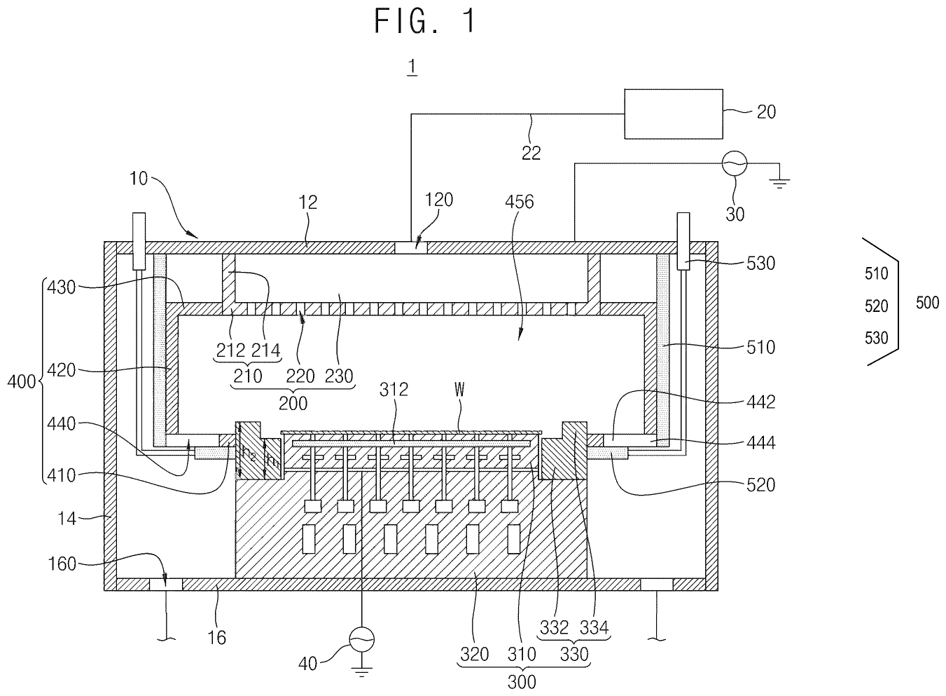

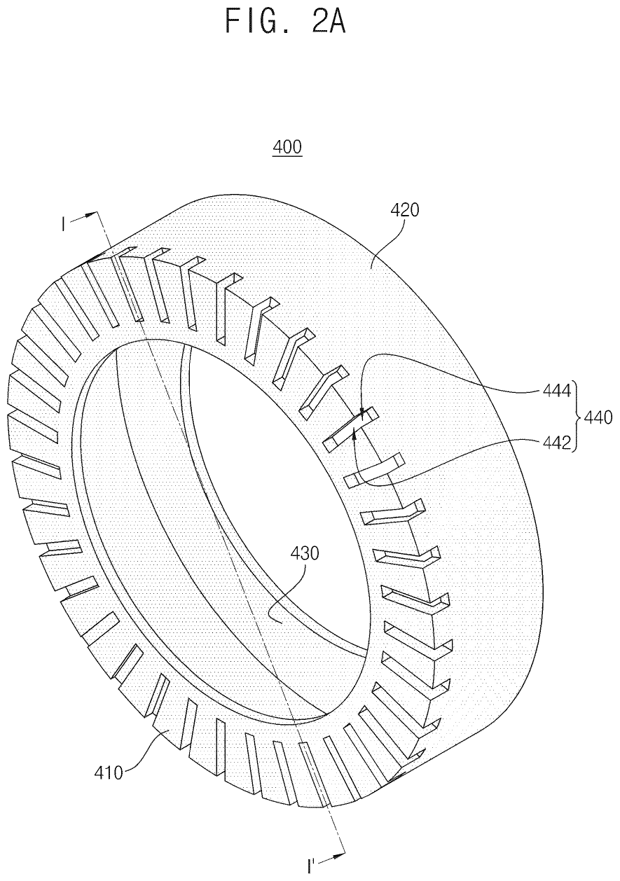

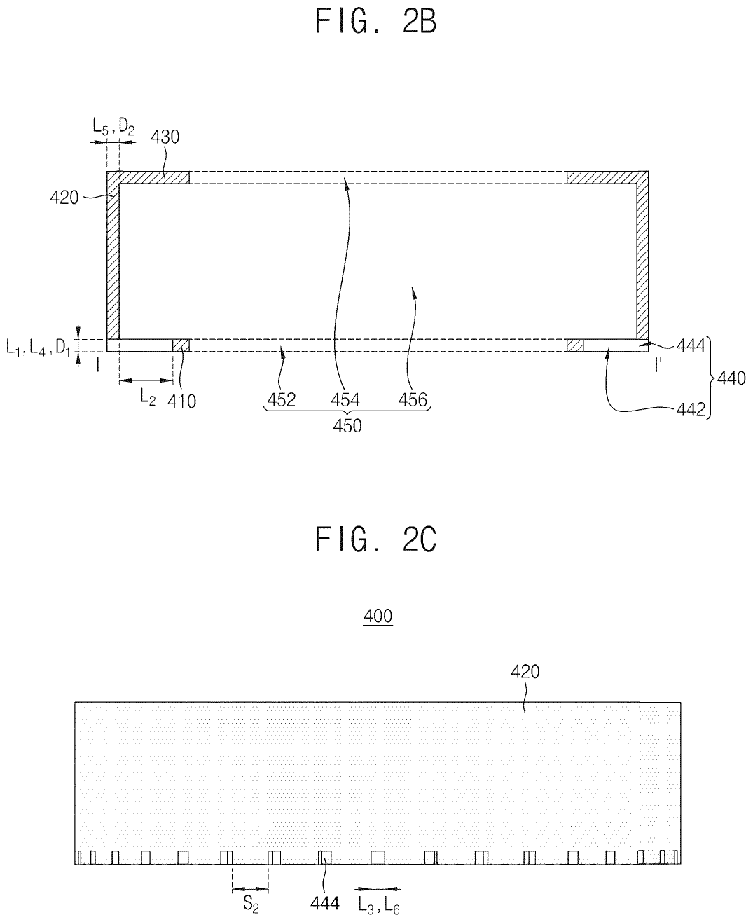

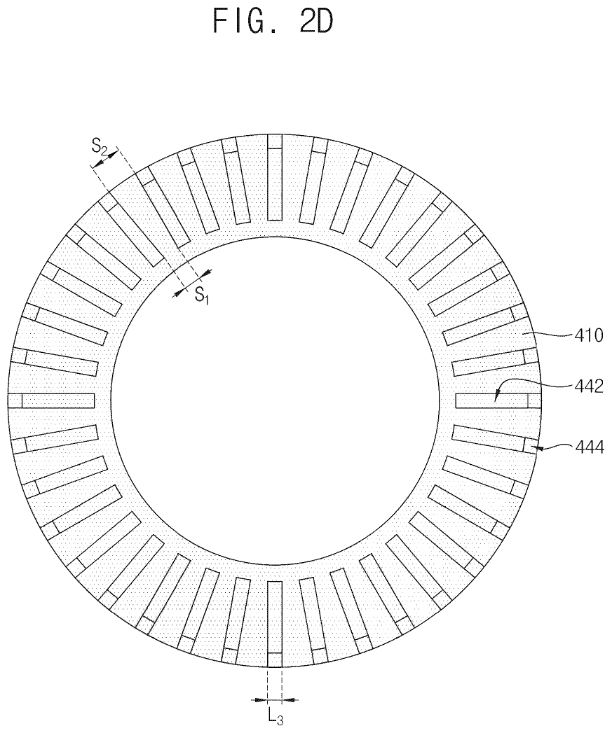

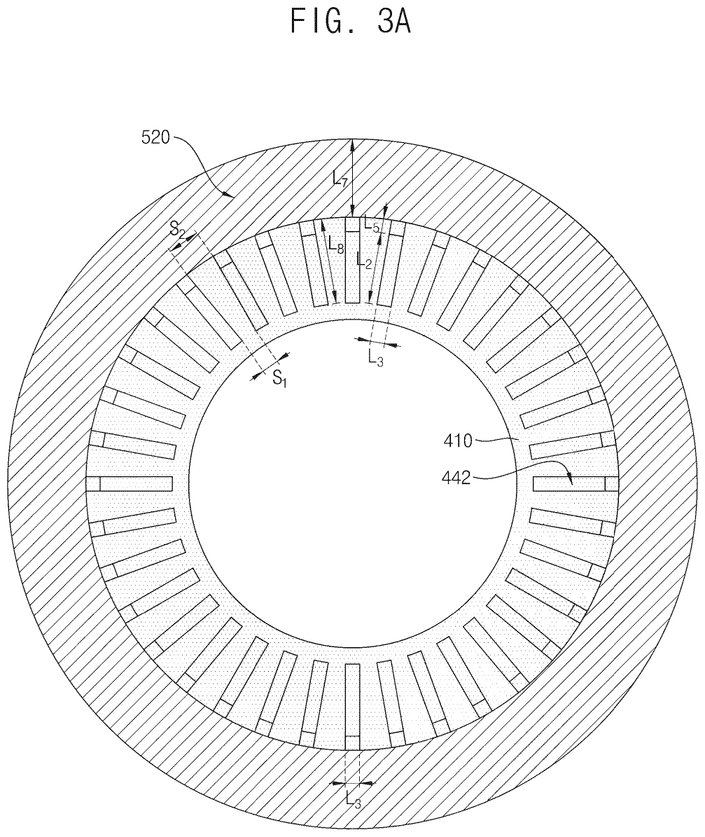

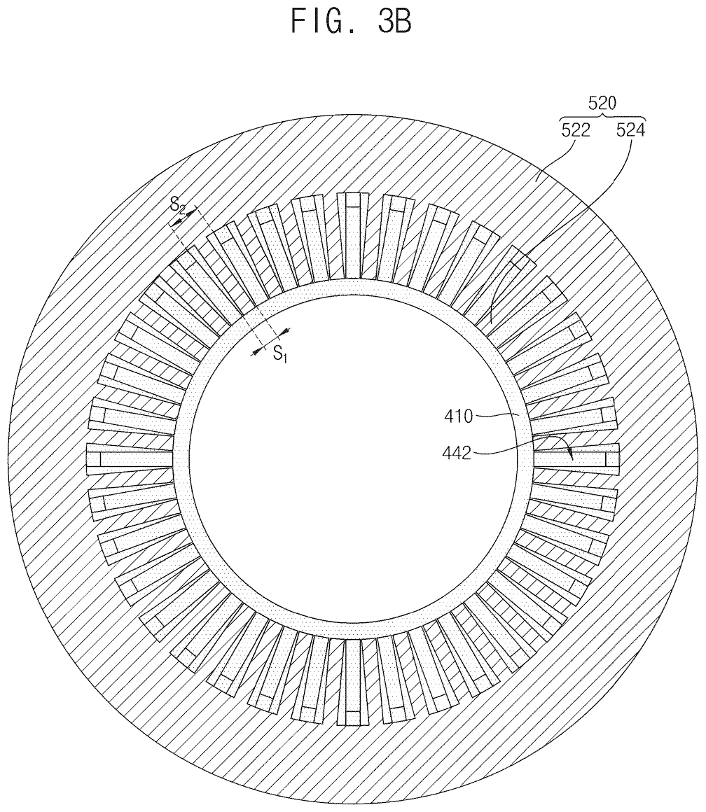

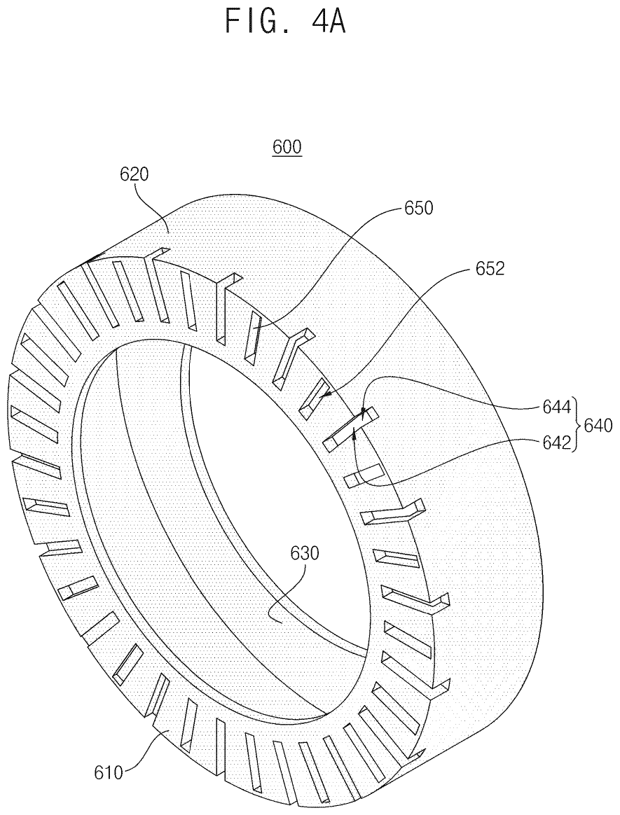

FIG. 1 is a vertical sectional view of a substrate processing apparatus according to some example embodiments of the inventive concepts. FIG. 2A is a perspective view of a shroud unit according to some example embodiments of the inventive concepts. FIG. 2B is a cross-sectional view taken along line I-I′ in FIG. 2A. FIG. 2C is a side view of a shroud unit according to some example embodiments of the inventive concepts. FIG. 2D is a bottom view of a shroud according to some example embodiments of the inventive concepts. FIG. 3A is a bottom view of a shroud unit and an opening/closing member according to some example embodiments of the inventive concepts. FIG. 3B is a bottom view of a shroud unit and an opening/closing member according to some example embodiments of the inventive concepts.

Referring to FIGS. 1 to 3A, a substrate processing apparatus 1 may include a process unit 10, a gas supply unit 20, a first power supply unit 30, and a second power supply unit 40. For example, the substrate processing apparatus 1 may be a capacitively coupled plasma apparatus capable of performing an etching process for a substrate.

The process unit 10 may be a chamber including a top wall 12, a side wall 14 and a bottom wall 16. A supply hole 120 may be provided at the top wall 12. The supply hole 120 may be formed to extend (e.g., may extend) vertically through the top wall 12 (e.g., an upper wall of the process unit). The supply hole 120 may be connected to the gas supply unit 20 (e.g., pressurized gas canister with actuated control valve) via a gas supply line 22. A discharge hole 160 may be provided at the bottom wall 16. The discharge hole 160 may be formed to extend vertically through the bottom wall 16.

An upper electrode unit 200, a lower electrode unit 300, a shroud unit 400, and an opening/closing unit 500 may be provided in an inner space (e.g., interior) of (e.g., at least partially defined by one or more inner surfaces of the top wall 12, side wall 14, and bottom wall 16 of) the process unit 10. A shroud unit 400 may be interchangeably referred to herein as a shroud structure. The upper electrode unit 200 may be disposed at an upper portion of the interior (e.g., inner space) of the process unit 10 (e.g., coupled to an upper end of the process unit 10 at an inner surface of the top wall 12 at least partially defining the inner space of the process unit 10 as shown in FIG. 1). The upper electrode unit 200 may include an upper electrode part 210, an injection hole 220, and a first space 230. The upper electrode part 210 may include a horizontal electrode member 212 disposed to be vertically spaced apart from the top wall 12, and vertical electrode members 214 extending vertically from one end and the other end of the horizontal electrode member 212, respectively, to connect the top wall 12 and the horizontal electrode member 212.

The upper electrode part 210 may include a metallic material. For example, the upper electrode part 210 may include a metal material such as aluminum, an aluminum alloy, steel, stainless steel, nickel, a nickel alloy (Inconel, Hastelloy, etc.), etc., or ceramic dielectrics such as quartz (SiO₂), SiC, SiN, Al₂O₃, AlN, Y₂O₃, etc. The upper electrode part 210, and thus the upper electrode unit 200, may receive (e.g., may be configured to receive, e.g., via electrically conductive contacts, wiring, etc.) first radio-frequency (RF) electric power from the first power supply unit 30, which is an external power supply unit (e.g., a battery, RF power supply, etc.). The upper electrode part 210 may perform a function of an upper electrode during execution of a process for a substrate W.

The injection hole 220 may be disposed at the upper electrode part 210. A plurality of injection holes 220 may be disposed while being horizontally spaced apart from one another. The injection hole 220 may be formed to extend vertically through the horizontal electrode member 212. The upper electrode part 210 and the injection hole 220 may be integrally formed. Alternatively, the injection hole 220 may be separately formed, and may then be disposed at the upper electrode part 210.

The first space 230 may be a space surrounded by the top wall 12 and the upper electrode part 210. A process gas from the gas supply unit 20 may be supplied to the first space 230 through the supply hole 120. For example, the process gas may include Cl, an inert gas such as F, NF₃, C₂F₆, CF₄, COS, SF₆, Cl₂, BCl₃, C₂HF₅, N₂, Ar, He, etc., H₂, and O₂. The process gas may include at least one of Cl, an inert gas, H₂, or O₂, where the insert gas may include at least one of F, NF₃, C₂F₆, CF₄, COS, SF₆, Cl₂, BCl₃, C₂HF₅, N₂, Ar, or He. The process gas may include at least one of CH, F, C, F₆, NF₃, NF₆, CHF₃, CF₄, Ar, or O₂. Heat from a heat supplier (not shown) may be supplied to the first space 230. The process gas in the first space 230 may be heated.

The lower electrode unit 300 may be disposed at a lower portion of the interior (e.g., inner space) of the process unit 10 (e.g., coupled to a lower end of the process unit 10 at an inner surface of the bottom wall 16 at least partially defining the inner space of the process unit 10 as shown in FIG. 1). The lower electrode unit 300 may support the substrate W. The lower electrode unit 300 may include a dielectric plate 310, a base plate 320, and a ring unit 330. The dielectric plate 310 may be dielectrics having a disc shape. The substrate W may be laid on an upper surface of the dielectric plate 310. The radius of the upper surface of the dielectric plate 310 may be smaller than the radius of the substrate W.

The dielectric plate 310 may include an electrostatic electrode 312 therein. An edge of the electrostatic electrode 312 may be aligned with an edge of the substrate W. The electrostatic electrode 312 may be electrically connected to an external power source. The electrostatic electrode 312 may receive electric power from the external power source. Electrostatic force may be generated between the electrostatic electrode 312 and the substrate W and, as such, the substrate W may be attracted to the upper surface of the dielectric plate 310.

The base plate 320 may be disposed at a lower surface of the dielectric plate 310. The base plate 320 may support the dielectric plate 310 and the ring unit 330. The base plate 320 may include a metal material. For example, the base plate 320 may include aluminum. The base plate 320 may be electrically connected to the second power supply unit 40 (e.g., a battery, RF power supply, etc.). The base plate 320, and thus the lower electrode unit 300, may receive (e.g., may be configured to receive, e.g., via electrically conductive contacts, wiring, etc.) second RF electric power from the second power supply unit 40. The frequency of the second RF electric power may be lower than the frequency of the first RF electric power. The base plate 320 may perform a function of a lower electrode attracting plasma ions to the substrate W.

The ring unit 330 may be disposed at an upper surface of the base plate 320. The ring unit 330 may control an electromagnetic field such that the density of plasma is uniformly distributed in the entire region of the substrate W. The ring unit 330 may include an inner part 332 and an outer part 334. The inner part 332 may surround a portion of a side surface of the dielectric plate 310, and may cover a portion of the upper surface of the base plate 320. An edge of the outer part 334 may be aligned with an edge of the base plate 320, and may cover a portion of the upper surface of the base plate 320. A lower surface of the inner part 332 and a lower surface of the outer part 334 may be coplanar. A height h₁ of the inner part 332 may be smaller than a height h₂ of the outer part 334. A step may be formed between an upper surface of the inner part 332 and an upper surface of the outer part 334.

The shroud unit 400 may be disposed at a central portion of the interior (e.g., inner space) of the process unit 10 as shown in FIG. 1. The shroud unit 400 may be disposed between the upper electrode unit 200 and the lower electrode unit 300 within the interior (e.g., inner space) of the process unit 10 as shown in FIG. 1. The shroud unit 400 may include a first flange part 410, a side wall part 420, a second flange part 430, a discharge part 440, and a second space 450.

The first flange part 410 may surround a portion of the lower electrode unit 300. The first flange part 410 may have a ring shape and thus may be a ring-shaped flange part. An outer side wall of the first flange part 410 may be connected to the side wall part 420.

The side wall part 420 may extend vertically from the first flange part 410 (e.g., an outer side wall of the first flange part 410, as shown in at least FIG. 2B) toward the second flange part 430. The side wall part 420 may connect the first flange part 410 and the second flange part 430. For example, the side wall part 420 may have a cylindrical shape. The second flange part 430 may surround a portion of the upper electrode unit 200. The second flange part 430 may have a ring shape. An outer side wall of the second flange part 430 may be connected to the side wall part 420.

As shown in FIGS. 1, 2A-2D, a shroud unit 400 may include one or multiple discharge parts 440 (e.g., first discharge parts).Each discharge part 440 may include a first slit 442 and a second slit 444. The first slit 442 may be formed to extend through (e.g., vertically through) the first flange part 410. The first slit 442 may extend from an inside of the first flange part 410 to an outside of the first flange part 410 (e.g., may extend through the first flange part 410). An inner end of the first slit 442 may be closed, and an outer end of the first slit 442 may be opened. For example, a vertical length L₁ of the first slit 442 may be equal to a height D₁ of the outer side wall of the first flange part 410. For example, the vertical length L₁ of the first slit 442 (e.g., magnitude thereof) may be about 7 mm to about 15 mm. A horizontal length L₂ of the first slit 442 (e.g., a magnitude thereof) may be about 5 to about 7 times the vertical length L₁ of the first slit 442 (e.g., a magnitude thereof). For example, the horizontal length L₂ of the first slit 442 (e.g., magnitude thereof) may be about 35 mm to about 105 mm. A width L₃ of the first slit 442 (e.g., magnitude thereof) may be about 2 mm to about 3 mm. The first slit 442 may be plural in number (e.g., quantity). In this case, the plurality of first slits 442 may be arranged to be spaced apart from one another by a first spacing S₁ in a circumferential direction of the first flange part 410. For example, the first spacing S₁ (e.g., magnitude thereof) may be about 1.5 mm to about 2.5 mm.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

The second slit 444 may be formed to extend horizontally through the side wall part 420 that is connected to the first flange part 410. The second slit 444 may be formed to extend from the side wall part 420 through the first flange part 410. The second slit 444 may be disposed at a lower portion of the side wall part 420. An upper end of the second slit 444 may be closed, and a lower end of the second slit 444 may be opened. The second slit 444 may extend vertically from the first slit 442 while extending through the side wall part 420. The second slit 444 may be connected to the first slit 442. The second slit 444 may be connected to the first slit 442 while extending through the side wall part 420 connected to the first flange part 410. A vertical length L₄ of the second slit 444 may be equal to the vertical length L₁ of the first slit 442. For example, the vertical length L₄ of the second slit 444 may be about 7 mm to about 15 mm. A horizontal length L₅ of the second slit 444 may be equal to a thickness D₂ of the side wall part 420. For example, the horizontal length L₅ of the second slit 444 may be about 10 mm to about 20 mm. A width L₆ of the second slit 444 may be equal to the width L₃ of the first slit 442. The second slit 444 may be plural in number. In this case, the plurality of second slits 444 may be arranged to be spaced apart from one another by a second spacing S₂ in a circumferential direction of the side wall part 420. For example, the second spacing S₂ may be about 2 mm to about 3 mm.

The second space 450, at least partially defined by one or more inner surfaces of the shroud unit 400 as shown in at least FIG. 2B, may include a first opening 452, a second opening 454, and a processing space 456. The first opening 452 may be defined by an inner side surface of the first flange part 410. The substrate W on the dielectric plate 310 of the lower electrode unit 300 and the ring unit 330 may be disposed at the first opening 452. The second opening 454 may be defined by an inner side surface of the second flange part 430. The horizontal electrode member 212 may be disposed at the second opening 454. The processing space 456 may be disposed between the first opening 452 and the second opening 454. The processing space 456 may be a space surrounded by (e.g., at least partially defined by) one or more structures of the substrate processing apparatus 1, the shroud unit 400, or the like. For example, the processing space 456 may be at least partially defined by respective inner surfaces of the first flange part 410, the side wall part 420, and the second flange part 430 from an outside (e.g., an exterior of the one or more structures defining the processing space 456, an exterior of the substrate processing apparatus 1, or the like). A process gas may be supplied from the upper electrode part 210 to the processing space 456. A process gas from the first space 230 may be supplied to the processing space 456. The process gas may be supplied through the injection hole 220. Plasma may be formed in the processing space 456 on the basis of the process gases. In the processing space 456, processing of the substrate W may be performed using the plasma. When processing of the substrate W is performed in the processing space 456, a processed gas may be produced. For example, the processed gas may include at least one of CH, F, C, F₆, NF₃, NF₆, CHF₃, CF₄, Ar, or O₂.

The opening/closing unit 500 may be located outside (e.g., external to) the shroud unit 400 and may include a fixing part 510, an opening/closing part 520, and a driving part 530. The fixing part 510 may be disposed outside the side wall part 420 of the shroud unit 400. The fixing part 510 may be disposed to be horizontally spaced apart from the side wall part 420. The fixing part 510 may be connected to the top wall 12. A lower surface of the fixing part 510 may be coplanar with a lower surface of the side wall part 420. As shown in at least FIGS. 1, 3A, and 3B, the opening/closing unit 500 may be outside (e.g., external to) the shroud unit 400 while surrounding the shroud unit 400 (e.g., surrounding in a horizontal plane).

The opening/closing part 520 may be disposed to be vertically spaced apart from a lower surface of the shroud unit 400 (e.g., from the first flange part 410). The opening/closing part 520 may be horizontally spaced apart from the side wall 14. For example, the opening/closing part 520 may be spaced apart from the side wall 14 by at least about 6 mm to about 10 mm. The opening/closing part 520 may vertically overlap with the first flange part 410. A side surface of the opening/closing part 520 may have a quadrangular shape. The opening/closing part 520 may surround at least a portion of the lower electrode unit 300.

As shown in FIG. 3A, a lower surface of the opening/closing part 520 may have a ring shape. The ring-shaped opening/closing part 520 may be vertically spaced apart from the side wall part 420, for example as shown in FIG. 1.

The fixing part 510 and the opening/closing part 520 may include at least one of quartz or silicon oxide (SiO₂). The driving part 530 may be provided at the top wall 12. The driving part 530 may perform control for the opening/closing part 520, thereby closing or opening the discharge part 440. For example, the driving part 530 may be a cylinder or a motor. The driving part 530 may perform control to retract or extract the opening/closing part 520. A horizontal length L₇ of the opening/closing part 520 may be increased or decreased in accordance with control of the driving part 530.

When processing of the substrate W is performed in the processing space 456, the driving part 530 may extract the opening/closing part 520 toward an outside of the opening/closing part 520, thereby closing the processing space 456. The driving part 530 may retract the opening/closing part 520 from the outside of the opening/closing part 520, thereby opening the processing space 456. A processed gas produced in the processing space 456 may be introduced into the discharge space through the discharge part 440. The processed gas introduced into the discharge space may be outwardly discharged through the discharge hole 160.

Referring to FIGS. 1 and 3B, in some example embodiments, the opening/closing part 520 may further include a support member 522, and one or a plurality of rotating members 524 extending horizontally (e.g., inwards) from a side surface (e.g., an inner end) of the support member 522. A horizontal length L₈ of each rotating member 524 may be equal to or greater than a sum of the horizontal length L₂ of the first slit 442 and the horizontal length L₅ of the second slit 444. A width L₉ of each rotating member 524 may be equal to or greater than the width L₃ of the first slit 442. When the opening/closing part 520 is configured as shown in FIG. 3B, the driving part 530 may close or open the processing space 456 by rotating the opening/closing part 520. Accordingly, the driving part 530 may be configured to rotate the opening/closing part 520 around a longitudinal axis thereof (e.g., around the shroud unit 400) to open/close the one or more discharge parts 440 of the shroud unit 400.

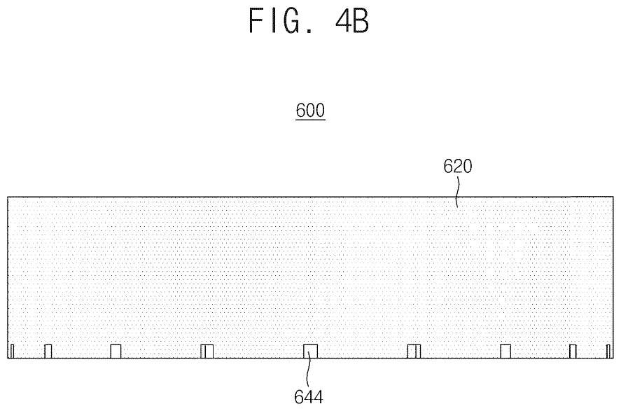

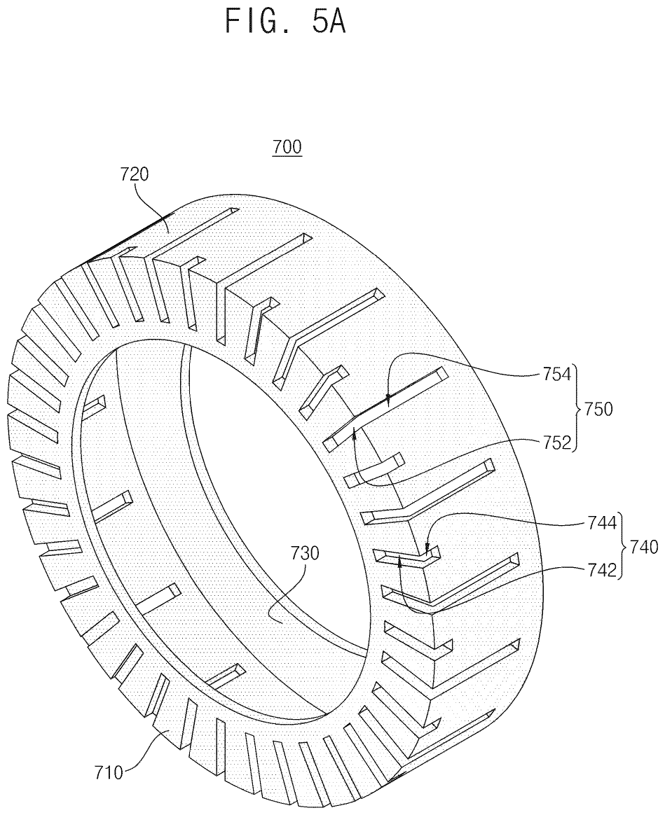

FIG. 4A is a perspective view of a shroud unit according to some example embodiments of the inventive concepts. FIG. 4B is a side view of the shroud unit according to some example embodiments of the inventive concepts.

Referring to FIGS. 4A and 4B, a shroud unit 600 may include a first flange part 610, a side wall part 620, a second flange part 630, a first discharge part 640, and a second discharge part 650. As shown in FIGS. 4A and 4B, a shroud unit 600 may include one or multiple first discharge parts 640. Each first discharge part 640 may include a first slit 642 and a second slit 644. The first slit 642 and the second slit 644 may be identical to the first slit 442 and the second slit 444 shown in FIGS. 2A to 2C, respectively. As shown in FIGS. 4A and 4B, a shroud unit 600 may include one or multiple second discharge parts 650. Each second discharge part 650 may include a third slit 652. The third slit 652 may be spaced apart from the side wall part 620. Accordingly, as shown in at least FIGS. 4A and 4B, the third slit 652 may be formed at (e.g., proximate to) the side wall part 620 while extending through the first flange part 610. The third slit 652 may be identical in shape to the first slit 642 (e.g., a shape of the first slit 642 may be identical to a shape of the third slit 652), except that the outer end of the first slit 642 is opened, whereas an outer end of the third slit 652 is closed. In some example embodiments, the third slit 652 may have a horizontal length different from the horizontal length of the first slit 642. Although the first discharge part 640 and the second discharge part 650 are shown as being alternately arranged one by one in the drawings, this arrangement is only illustrative. The first discharge part 640 and the second discharge part 650 may be arranged in any arrangement. For example, one second discharge part 650 may be disposed between adjacent pairs of first discharge parts 640.

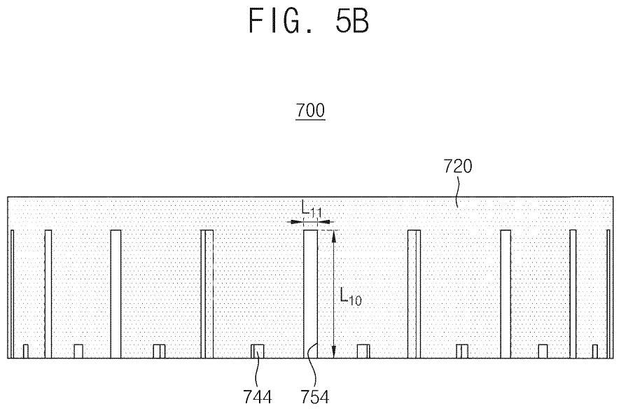

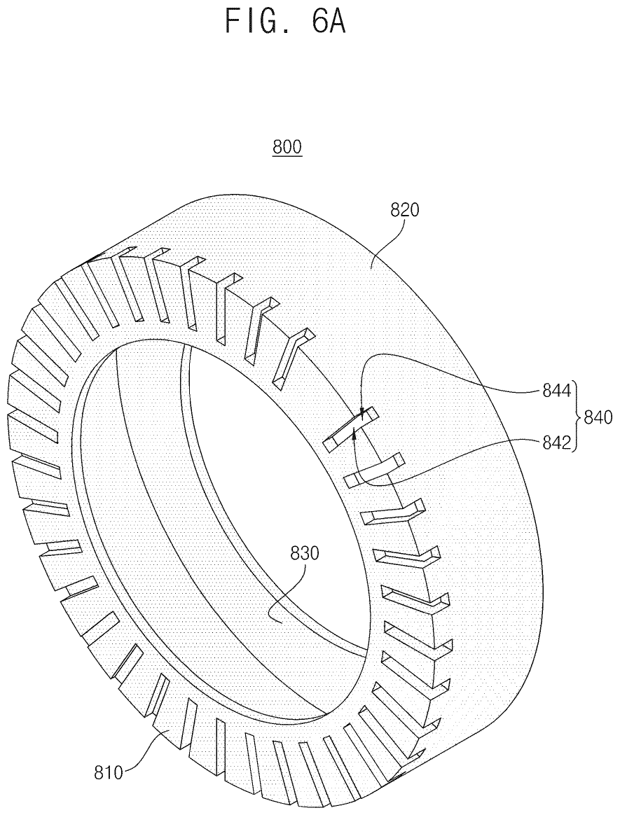

FIG. 5A is a perspective view of a shroud unit according to some example embodiments of the inventive concepts. FIG. 5B is a side view of the shroud unit according to some example embodiments of the inventive concepts.

Referring to FIGS. 5A and 5B, a shroud unit 700 may include a first flange part 710, a side wall part 720, a second flange part 730, one or more first discharge parts 740, and one or more second discharge parts 750. The first discharge part 740 (e.g., each of the first discharge parts 740) may include a first slit 742 and a second slit 744. The first slit 742 and the second slit 744 may be identical to the first slit 442 and the second slit 444 shown in FIGS. 2A to 2C, respectively. The second discharge part 750 (e.g., each of the second discharge parts 750) may include a third slit 752 and a fourth slit 754. The third slit 752 may be identical to the first slit 642. The fourth slit 754 may extend horizontally through the side wall part 72. The fourth slit 754 may be connected to the third slit 752. The fourth slit 754 may be closed at an upper end thereof while being opened at a lower end thereof. A vertical length L₁₀ of the fourth slit 754 may be greater than the thickness of the first flange part 710. A vertical length L₁₀ of the fourth slit 754 may be different from (e.g., greater than) a vertical length of the second slit 744. The vertical length L₁₀ of the fourth slit 754 may be greater than a horizontal length L₁₁ of the fourth slit 754.

Referring to FIGS. 4A-5B, the substrate processing apparatus 1 including at least one of the shroud units 600, 700 shown therein may include an opening/closing unit 500 as described above with reference to FIGS. 1-3B, where the opening/closing unit 500 may be located outside the shroud unit 600, 700 and may be configured to open/close the first discharge parts 640, 740 and the second discharge parts 650, 750. Said opening/closing unit may include a fixing part 510, an opening/closing part 520, and a driving part 530 as described herein, where the driving part 530 may be configured to perform control of the opening/closing part 520 to open/close at least one of the first discharge parts 640, 740 or the second discharge parts 650, 750.

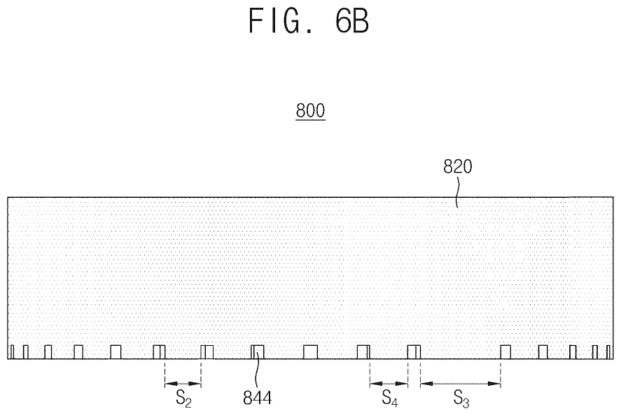

FIG. 6A is a perspective view of a shroud unit according to some example embodiments of the inventive concepts. FIG. 6B is a side view of the shroud unit according to some example embodiments of the inventive concepts.

Referring to FIGS. 6A and 6B, a shroud unit 800 may include a first flange part 810, a side wall part 820, a second flange part 830, and a discharge part 840. The discharge part 840 may include a first slit 842 and a second slit 844. A spacing S₃ between adjacent ones of at least two discharge parts 840 may differ from a spacing S₄ between adjacent ones of the remaining discharge parts 840. For example, the spacing S₃ between adjacent ones of at least two discharge parts 840 may be two times the first spacing S₁, whereas the spacing S₄ between adjacent ones of the remaining discharge parts 840 may be equal to the first spacing S₁.

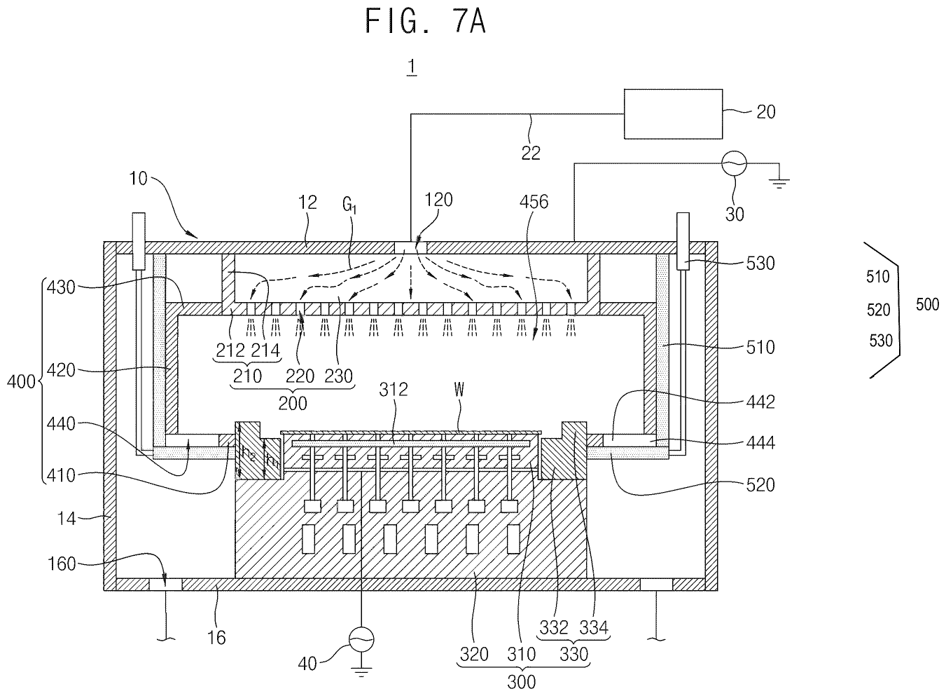

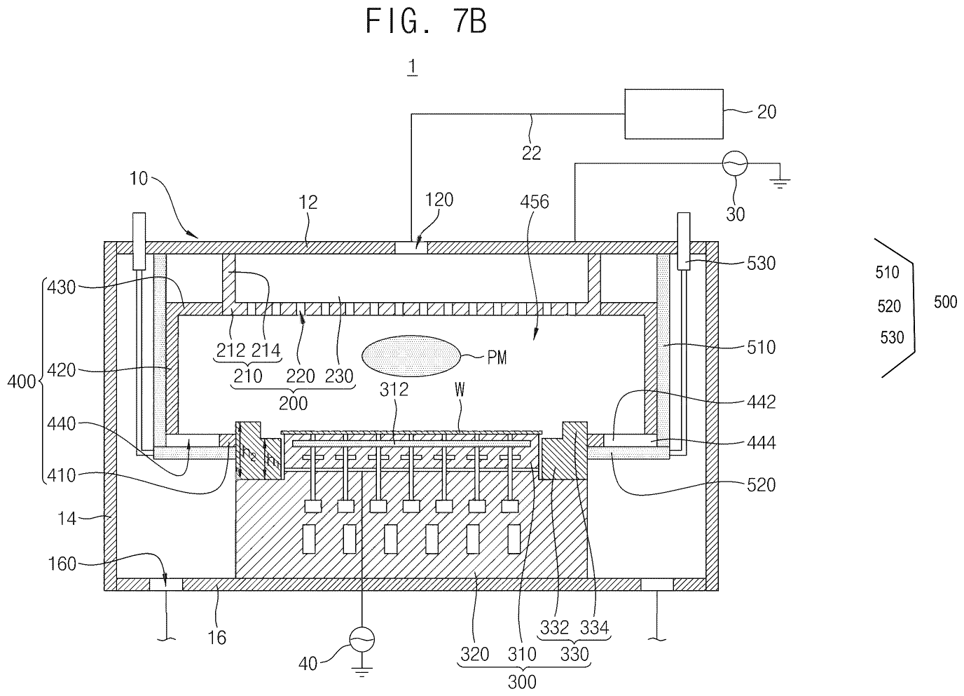

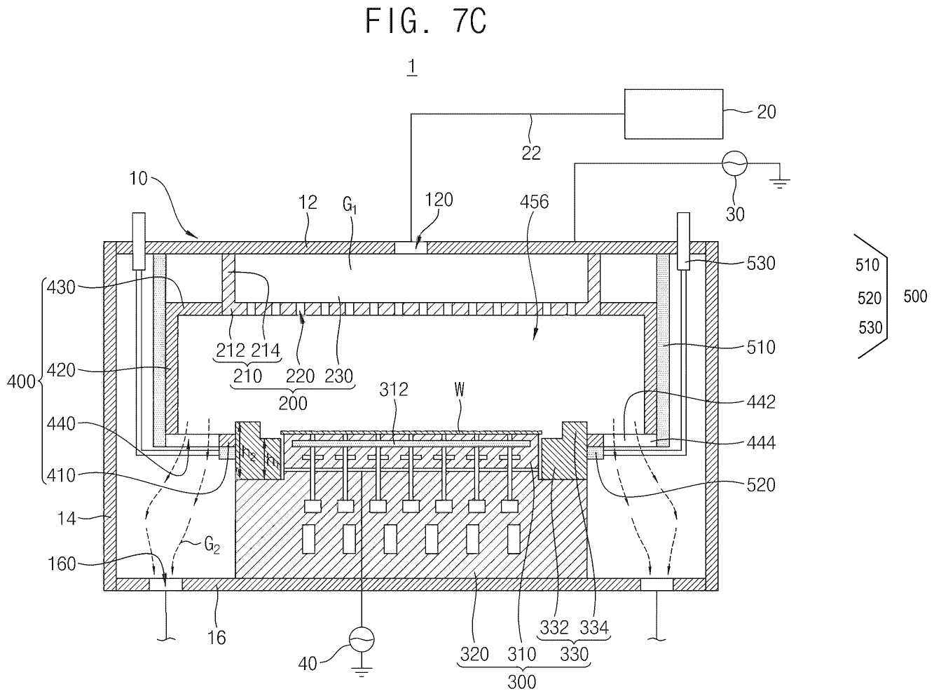

FIGS. 7A, 7B, and 7C are schematic views of a substrate processing method according to some example embodiments of the inventive concepts.

Referring to FIG. 7A, a substrate W may be inserted into a processing space 456 from an outside (e.g., an exterior of one or more structures having one or more inner surfaces at least partially defining the processing space within an interior thereof, for example an exterior of the shroud unit 400, an exterior of the process unit 10, or the like). An exterior of one or more structures may include an exterior of a volume defined by one or more outer surfaces of the one or more structures. An opening/closing unit 500 may close a discharge part 440 of a shroud unit 400, which is in an opened state. A driving part 530 of the opening/closing unit 500 controls an opening/closing part 520, thereby closing the discharge part 440 of the shroud unit 400. For example, when the opening/closing part 520 is configured as shown in FIG. 3A, the driving part 530 may close the discharge part 440 by horizontally moving the opening/closing part 520. When the opening/closing part 520 is configured as shown in FIG. 3B, the driving part 530 may close the discharge part 440 by rotating the opening/closing part 520. After the discharge part 440 is closed, a gas supply unit 20 may supply a process gas G₁ to an interior of the process unit 10, such that the process gas G₁ may be received from the gas supply unit 20 to the processing space 456. The process gas G₁ may be supplied to a first space 230 of an upper electrode unit 200 through a supply hole 120. The process gas G₁ may be heated by heat supplied from a heat supplier (not shown). The heated process gas G₁ may be injected into a processing space 456 of the shroud unit 400 through an injection hole 220 of the upper electrode unit 200.

Referring to FIG. 7B, first RF electric power may be applied from a first power supply unit 30 to an upper electrode part 210. Plasma PM may be produced in accordance with a method in which the process gas G₁ in the processing space 456 is excited to a plasma state, for example based on the first RF power being applied to the upper electrode part 210. Accordingly, the plasma PM may be produced based on the process gas G₁. Second RF electric power may be applied from a second power supply unit 40 (e.g., a battery, RF power supply, etc. to a lower electrode unit 300. The frequency of the second RF electric power may be lower than the frequency of the first RF electric power. Ions of the plasma PM are moved to the substrate W laid on a dielectric plate 310 of the lower electrode unit 300 and, as such, an etching process for the substrate W (e.g., an etching process to cause etching of the substrate W to be performed) may be performed (e.g., using ions included in the plasma PM).

Referring to FIG. 7C, in accordance with the etching process, a processed gas G₂ may be produced in the discharge part 440 of the shroud unit 400. Restated, a processed gas G₂ may be produced in (e.g., during, based on, etc.) the etching process. The opening/closing unit 500 may open the discharge part 440 of the closed shroud unit 400. The driving part 530 of the opening/closing unit 500 may open the discharge part 440 of the shroud unit 400 by performing control of the opening/closing part 520. For example, when the opening/closing part 520 is configured as shown in FIG. 3A, the driving part 530 may open the discharge part 440 by horizontally moving the opening/closing part 520. When the opening/closing part 520 is configured as shown in FIG. 3B, the driving part 530 may open the discharge part 440 by rotating the opening/closing part 520. The processed gas G₂ in the processing space 456 may be outwardly discharged through the discharge hole 160 and thus may be discharged (e.g., from the shroud unit 400, from the process unit 10, etc.) through the discharge part 440 of the shroud unit 400.

In some example embodiments, some or all of the methods described herein may be controlled by a control device (e.g., a control device which may be configured to control some or all of the substrate processing apparatus 1). Said control device may include, may be included in, and/or may be implemented by one or more instances of processing circuitry such as hardware including logic circuits; a hardware/software combination such as a processor executing software; or a combination thereof. For example, the processing circuity more specifically may include, but is not limited to, a central processing unit (CPU), an arithmetic logic unit (ALU), an application processor (AP), a microcomputer, a field programmable gate array (FPGA), and programmable logic unit, a microprocessor, application-specific integrated circuit (ASIC), a neural network processing unit (NPU), an Electronic Control Unit (ECU), and the like. In some example embodiments, the processing circuitry may include a non-transitory computer readable storage device, for example a solid state drive (SSD), storing a program of instructions, and a processor (e.g., CPU) configured to execute the program of instructions to implement the functionality and/or methods performed by the control device, including controlling some or all of the substrate processing apparatus 1 to perform some or all of the methods of any of the example embodiments, including the method shown in FIGS. 7A-7C.

In accordance with some example embodiments of the inventive concepts, the etching rate in an edge region of a semiconductor device may be increased and, as such, the throughput yield of the semiconductor device may be enhanced.

While some example embodiments of the inventive concepts have been described with reference to the accompanying drawings, it should be understood by those skilled in the art that various transitions may be made without departing from the scope of the inventive concepts and without changing essential features thereof. Therefore, the above-described example embodiments should be considered in a descriptive sense only and not for purposes of limitation.

What is claimed is:

1. A substrate processing method, comprising:
inserting a substrate into a processing space at least partially defined by one or more inner surfaces of a shroud unit from an outside of a volume defined by one or more outer surfaces of the shroud unit;
receiving a process gas from a gas supply unit to the processing space;
producing plasma based on the process gas;
performing an etching process to cause etching of the substrate using ions included in the plasma; and
discharging a processed gas produced in the etching process through a discharge part of the shroud unit,
wherein the discharge part includes a first slit extending through a flange part, and a second slit connected to the first slit while extending through a side wall part connected to the flange part,
wherein a vertical length of the first slit is equal to a vertical length of the second slit,
wherein a horizontal length of the first slit is about 5 times to about 7 times the vertical length of the first slit, and
wherein an opening/closing unit performs opening/closing of the discharge part to discharge the processed gas produced in the etching process, the opening/closing unit including a fixing part, an upper surface of the fixing part is in direct contact with a top wall of a process unit and outside the side wall part, a lower surface of the fixing part is coplanar with a lower surface of the side wall part.

2. The substrate processing method according to claim 1, wherein:
the process gas includes at least one of Cl, an inert gas, H₂, or O₂; and
the inert gas includes at least one of F, NF₃, C₂F₆, CF₄, COS, SF₆, Cl₂, BCl₃, C₂HF₅, N₂, Ar, or He.

3. The substrate processing method according to claim 1, wherein the process gas includes at least one of CH, F, C, F₆, NF₃, NF₆, CHF₃, CF₄, Ar, or O₂.

4. The substrate processing method according to claim 1, wherein:
the first slit is closed at an inner end of the first slit while being opened at an outer end of the first slit; and
the second slit is closed at an upper end of the second slit while being opened at a lower end of the second slit.

5. The substrate processing method according to claim 1, wherein a width of the first slit is equal to a width of the second slit.

6. The substrate processing method according to claim 1, wherein the vertical length of the first slit is about 7 mm to about 15 mm.

7. The substrate processing method according to claim 1, wherein the horizontal length of the first slit is about 35 mm to about 105 mm.

8. The substrate processing method according to claim 1, wherein a horizontal length of the second slit is equal to a thickness of the side wall part.

9. The substrate processing method according to claim 1, wherein the vertical length of the second slit is about 7 mm to about 15 mm.

10. A substrate processing apparatus, comprising:
a process unit;
an upper electrode unit at an upper portion of an interior of the process unit, the upper electrode unit configured to receive first radio-frequency (RF) electric power from a first power supply unit;
a lower electrode unit at a lower portion of the interior of the process unit, the lower electrode unit configured to receive second RF electric power from a second power supply unit; and
a shroud unit between the upper electrode unit and the lower electrode unit within the interior of the process unit,
wherein the shroud unit includes
a first flange part,
a second flange part,
a side wall part extending vertically from an outer side wall of the first flange part to the second flange part, and
first discharge parts each including a first slit extending through the first flange part, the first slit extending from an inside of the first flange part to an outside of the first flange part, and
wherein an inner end of the first slit is closed and an outer end of the first slit is opened,
wherein a vertical length of the first slit is equal to a height of the outer side wall of the first flange part, and
wherein a horizontal length of the first slit is about 5 to about 7 times the vertical length of the first slit.

11. The substrate processing apparatus according to claim 10,
wherein the first discharge parts include a second slit, the second slit is formed to extend from the side wall part through the first flange part so that an upper end of the second slit is closed and a lower end of the second slit is open.

12. The substrate processing apparatus according to claim 11, wherein a vertical length of the second slit is equal to the vertical length of the first slit.

13. The substrate processing apparatus according to claim 11, wherein a horizontal length of the second slit is equal to a thickness of the side wall part.

14. The substrate processing apparatus according to claim 11, wherein a width of the second slit is equal to a width of the first slit.

15. The substrate processing apparatus according to claim 10, further comprising:
an opening/closing unit outside the shroud unit while surrounding the shroud unit, the opening/closing unit including a fixing part, an upper surface of the fixing part is in direct contact with a top wall of the process unit and outside the side wall part, a lower surface of the fixing part is coplanar with a lower surface of the side wall part,
wherein the opening/closing unit includes
an opening/closing part vertically spaced apart from a ring-shaped flange part; and
a driving part configured to perform control of the opening/closing part to open/close at least one of the first discharge parts.

16. The substrate processing apparatus according to claim 15, wherein the driving part is configured to retract or extract the opening/closing part.

17. The substrate processing apparatus according to claim 15, wherein:
the opening/closing part includes a support member, and a rotating member extending horizontally from a side surface of the support member; and
a horizontal length of the rotating member is equal to the horizontal length of the first slit.

18. A substrate processing apparatus, comprising:
a process unit;
a supply hole extending through a top wall of the process unit;
an upper electrode unit at an upper portion of an interior of the process unit, the upper electrode unit configured to receive first radio-frequency (RF) electric power from a first power supply unit;
a lower electrode unit at a lower portion of the process unit, the lower electrode unit configured to receive second RF electric power from a second power supply unit;
a shroud unit between the upper electrode unit and the lower electrode unit within the interior of the process unit;
an opening/closing unit outside the shroud unit while surrounding the shroud unit, the opening/closing unit including a fixing part, an upper surface of the fixing part is in direct contact with the top wall of the process unit and outside a side wall part, a lower surface of the fixing part is coplanar with a lower surface of the side wall part; and
a discharge hole extending through a bottom wall of the process unit,
wherein the shroud unit includes
a ring-shaped flange part,
the side wall part extending vertically from an outer side wall of the ring-shaped flange part, and
a discharge part including a first slit extending through the ring-shaped flange part, and a second slit extending vertically from the first slit while extending through the side wall part, and
wherein vertical lengths of the first slit and the second slit are equal.

19. The substrate processing apparatus according to claim 18, wherein the opening/closing unit comprises:
a ring-shaped opening/closing part vertically spaced apart from the side wall part; and
a driving part configured to retract or extract the ring-shaped opening/closing part to open/close the discharge part.

20. The substrate processing apparatus according to claim 18, wherein:
the opening/closing unit includes
an opening/closing part vertically spaced apart from the ring-shaped flange part, and
a driving part configured to rotate the opening/closing part to open/close the discharge part;
the opening/closing part includes
a support member, and
a rotating member extending horizontally from the support member; and
a horizontal length of the rotating member is equal to a sum of a horizontal length of the first slit and a horizontal length of the second slit.
